(19) United States
(12) Patent Application Publication
(10) Pub. No.: US 2018/0057632 A1
(43) Pub. Date: Mar. 1, 2018

(54) CONDUCTIVE COMPOSITION FOR FORMING SOLAR CELL COLLECTOR ELECTRODE, SOLAR CELL, AND SOLAR CELL MODULE

(71) Applicant: THE YOKOHAMA RUBBER CO., LTD., MINATO-KU, TOKYO (JP)

(72) Inventors: Nao SATO, HIRATSUKA-CITY, KANAGAWA (JP); Kazunori ISHIKAWA, HIRATSUKA-CITY, KANAGAWA (JP)

(21) Appl. No.: 15/545,519

(22) PCT Filed: Jun. 25, 2015
(86) PCT No.: PCT/JP2015/068374

§ 371 Date: Jul. 21, 2017

(30) Foreign Application Priority Data
Jul. 11, 2014 (JP) 2014-143055

(51) Int. Cl. C08G 59/58; C08K 3/08; H01B 1/22; H01L 31/0224; H01L 31/0747; H01L 31/02; H01L 31/05; H01L 31/0216

(52) U.S. Cl. CPC C08G 59/58; C08K 3/08; H01B 1/22; H01L 31/0224; H05K 1/092; H01L 31/02008; H01L 31/0504; H01L 31/02168; C03C 2214/08; H01L 31/0747

(57) ABSTRACT

An object of the present invention is to provide: a conductive composition for forming a solar cell collector electrode that can form a collector electrode with favorable adhesion with regard to a transparent conductive layer; a solar cell having a collector electrode formed using the composition; and a solar cell module. A conductive composition for forming a solar cell collector electrode, includes: a metal powder (A); an epoxy resin (B); a cationic curing agent (C); and a blocked carboxylic acid (D); wherein the blocked carboxylic acid (D) is a compound obtained by reacting a compound (d1) selected from carboxylic acids and carboxylic acid anhydrides with a vinyl ether compound (d2).

### TECHNICAL FIELD

The present invention relates to a conductive composition for forming a solar cell collector electrode, a solar cell, and a solar cell module.

### BACKGROUND ART

Various structures and configurations of solar cells that convert high energy such as sunlight into electrical energy have been positively developed in conjunction with increasing interest in global environmental issues. Of these, solar cells using a semiconductor substrate of silicon or the like are most generally used for advantages such as conversion efficiency, manufacturing cost, and the like.

Epoxy resin paste material is known as a material that forms electrodes for solar cells.

For example, Patent Document 1 describes “A conductive paste, comprising:

a metal powder (A);

a resin having a group that can react with a carboxyl group (B); and

a curing agent that can react with the resin (C); wherein

the curing agent is a latent carboxyl group-generating compound (C)”.

### ([Claim 1]).

### CITATION LIST

### Patent Literature

Patent Document 1: Japanese Unexamined Patent Application Publication No. 2004-355933A

### SUMMARY OF INVENTION

### Technical Problem

However, as a result of studying the conductive paste described in Patent Document 1, the present inventors discovered that when a collector electrode is formed on a transparent conductive layer (such as a transparent conductive oxide layer (TCO)), adhesion between the transparent conductive layer and collector electrode may be inferior.

Therefore, an object of the present invention is to provide: a conductive composition for forming a solar cell collector electrode that can form a collector electrode with favorable adhesion with regard to a transparent conductive layer; a solar cell having a collector electrode formed using the composition; and a solar cell module.

### Solution to Problem

As a result of extensive studies in order to resolve the aforementioned problem, the present inventors discovered that by using a cationic curing agent as an epoxy resin curing agent along with a blocked carboxylic acid, an electrode with favorable adhesion with regard to a transparent conductive layer is formed, thereby completing the present invention.

In other words, the present inventors discovered that the problems described above can be resolved by the following configurations.

[1] A conductive composition for forming a solar cell collector electrode, including: a metal powder (A); an epoxy resin (B); a cationic curing agent (C); and a blocked carboxylic acid (D); wherein the blocked carboxylic acid (D) is a compound obtained by reacting a compound (d1) selected from carboxylic acids and carboxylic acid anhydrides with a vinyl ether compound (d2).

[2] The conductive composition for forming a solar cell collector electrode according to [1], wherein the amount of the blocked carboxylic acid (D) is 0.05 to 5 parts by mass with regard to 100 parts by mass of the metal powder (A).

[3] The conductive composition for forming a solar cell collector electrode according to [1] or [2], wherein the metal powder (A) contains both spherical metal powder (A1) and flaky metal powder (A2) at a mass ratio (A1:A2) of 70:30 to 30:70.

[4] The conductive composition for forming a solar cell collector electrode according to any one of [1] to [3], wherein the blocked carboxylic acid (D) is a polymeric blocked carboxylic acid obtained by addition polymerizing a dicarboxylic acid and a divinyl ether compound.

[5] The conductive composition for forming a solar cell collector electrode according to any one of [1] to [4], wherein the number of carbon atoms in the compound (d1) is 3 to 9.

[6] The conductive composition for forming a solar cell collector electrode according to any one of [1] to [5], wherein the number of carbon atoms in the compound (d1) is any one of 3, 5, 7 or 9.

[7] The conductive composition for forming a solar cell collector electrode according to any one of [1] to [6], wherein the compound (d1) is at least one type of dicarboxylic acid selected from the group consisting of malonic acid, glutaric acid, pimelic acid, and azelaic acid.

[8] A solar cell, including: a collector electrode; and a transparent conductive layer as a foundation layer of the collector electrode; wherein the collector electrode is formed using the conductive composition for forming a solar cell collector electrode according to any one of [1] to [7].

[9] A solar cell module using the solar cell according to [8].

### Advantageous Effects of Invention

As described below, the present invention can provide: a conductive composition for forming a solar cell collector electrode that can form a collector electrode with favorable adhesion with regard to a transparent conductive layer; a solar cell having a collector electrode formed using the composition; and a solar cell module.

Furthermore, if the conductive composition for forming a solar cell collector electrode of the present invention is used, a collector electrode with favorable adhesion with regard to a transparent conductive layer can be formed even if baked at a low temperature (450° C. or lower (and particularly 200° C. or lower)), and therefore, there is an effect where damage to the solar cell due to heat can be reduced, which is very useful.

### BRIEF DESCRIPTION OF DRAWINGS

FIG. 1 is a cross-sectional view illustrating an example of a preferred embodiment of a solar cell.

### DESCRIPTION OF EMBODIMENTS

A conductive composition for forming a solar cell collector electrode of the present invention (hereinafter, simply referred to as “conductive composition of the present invention”), a solar cell having a collector electrode formed using the composition, and a solar cell module will be described below.

Note that, in the present specification, numerical ranges indicated using “(from) . . . to . . . ” include the former number as the lower limit value and the latter number as the upper limit value.

### Conductive Composition

The conductive composition of the present invention is a conductive composition for forming a solar cell collector electrode, including: a metal powder (A); an epoxy resin (B); a cationic curing agent (C); and a blocked carboxylic acid (D); where the blocked carboxylic acid (D) is a compound obtained by reacting a compound (d1) selected from carboxylic acids and carboxylic acid anhydrides with a vinyl ether compound (d2).

Furthermore, the conductive composition of the present invention may include, as necessary, a phenoxy resin (E), a fatty acid metal salt (F), a solvent (G), or the like as described below.

As described above, in the present invention, a predetermined blocked carboxylic acid (D) is blended along with the cationic curing agent (C), and therefore a conductive composition that can form an electrode with favorable adhesion with regard to a transparent conductive layer is obtained.

Although the reason is not clear in detail, it is assumed to be as follows.

First, it is thought that the blocked carboxylic acid (D) produces a carboxylic acid with the block removed during heating and drying when forming an electrode or the like, the carboxy group of the carboxylic acid reacts with the epoxy resin (B), and a curing reaction proceeds.

Furthermore, at least a portion of the generated carboxylic acid is thought to remain in the system without reacting with the epoxy resin (B) due to the cationic curing agent (C) being separately present in the system, and adhesion to the transparent conductive layer is thought to be expressed due to the high polarity of the remaining carboxylic acid.

The metal powder (A), epoxy resin (B), cationic curing agent (C), and blocked carboxylic acid (D) included in the conductive composition of the present invention, as well as other components that may be included as desired will be described below.

### Metal Powder (A)

The metal powder (A) included in the conductive composition of the present invention is not particularly limited, and a metal material with an electrical resistivity of 20×10⁻⁶ Ω·cm or lower can be used for example.

Specific examples of the metal material include gold (Au), silver (Ag), copper (Cu), aluminum (Al), magnesium (Mg), nickel (Ni), and the like, and one type may be used independently or two or more types may be used in combination.

Of these, silver powder and copper powder are preferred, and a silver powder is more preferred, from the perspective that a collector electrode with low contact resistance can be formed.

Note that the silver powder may be a silver-coated metal powder in which silver is coated on a surface of a metal powder other than silver (such as a nickel powder, copper powder, or the like).

In the present invention, the metal powder (A) is preferably a spherical metal powder (A1), more preferably a flaky (scaly) metal powder (A2) along with the spherical metal powder (A1), and more preferably contains both the spherical metal powder (A1) and flaky metal powder (A2) at a ratio where the mass ratio (A1:A2) is 70:30 to 30:70, from the perspective of favorable printing properties (and particularly, screen printing properties).

Herein, “spherical” refers to the shape of particles having a major axis/minor axis ratio of 2 or less, and “flaky” refers to a shape where the major axis/minor axis ratio exceeds 2.

The average particle size of the spherical metal powder (A1) as the metal powder (A) is preferably 0.5 to 10 μm, and more preferably 0.5 to 5.0 μm, from the perspective of more favorable printing properties.

Herein, the average particle size of the spherical metal powder (A1) refers to the average value of the particle size of the spherical metal powder, and refers to a 50% volume cumulative diameter (D50) measured using a laser diffraction type particle size distribution measuring device. Note that the particle size serving as a basis for calculating the average value refers to an average value where the total value of a major axis and minor axis is divided by 2 when a cross section of the metal powder is elliptical, and refers to a diameter when a regular circle.

The average thickness of the flaky metal powder (A2) as the metal powder (A) is preferably 0.05 to 2.0 μm, and more preferably 0.05 to 1.0 μm, from the perspective of more favorable printing properties and ease of forming a paste.

Herein, the average thickness of the flaky metal powder (A2) refers to a value calculated from the following Equation (i) as S (m²/g), where the specific surface area of the flaky metal powder is measured by the BET method (gas adsorption method).

Average thickness=0.19/S (i)

In the present invention, a commercially available product can be used as the metal powder (A).

Specific examples of commercially available products of a spherical silver powder include: AG2-1C (average particle size: 1.0 μm, manufactured by DOWA Electronics Materials Co., Ltd.), AG4-8F (average particle size: 2.2 μm, manufactured by DOWA Electronics Materials Co., Ltd.), AG3-11F (average particle size: 1.4 μm, manufactured by DOWA Electronics Materials Co., Ltd.), AgC-102 (average particle size: 1.5 μm, manufactured by Fukuda Metal Foil & Powder Co., Ltd.), AgC-103 (average particle size: 1.5 μm, manufactured by Fukuda Metal Foil & Powder Co., Ltd.), EHD (average particle size: 0.5 μm, manufactured by Mitsui Mining & Smelting Co., Ltd.), and the like.

Furthermore, specific examples of commercially available products of a flaky silver powder include Ag-XF301K (average size: 0.1 μm, manufactured by Fukuda Metal Foil & Powder Co., Ltd.), and the like.

### Epoxy Resin (B)

The epoxy resin (B) used in the conductive composition of the present invention is not particularly limited so long as the resin includes a compound having at least two oxirane rings (epoxy groups), and generally has an epoxy equivalent weight of 90 to 2000 g/eq.

Conventionally known epoxy resins can be used as the epoxy resin.

Specific examples include difunctional glycidyl ether epoxy resins such as bisphenol group-bearing epoxy compounds (e.g., bisphenol A, bisphenol F, brominated bisphenol A, hydrogenated bisphenol A, bisphenol S, bisphenol AF, biphenyl, and the like epoxy compounds), polyalkylene glycol and alkylene glycol epoxy compounds, naphthalene ring-bearing epoxy compounds, fluorene group-containing epoxy compounds, and the like; polyfunctional glycidyl ether epoxy compounds (e.g., phenolic novolak, orthocresol novolak, trishydroxyphenylmethane, trifunctional, tetraphenylethane, and the like epoxy compounds); glycidyl ester epoxy resins of synthetic fatty acids such as dimer acid and the like; glycidylamine epoxy resins, such as N,N,N′,N′-tetraglycidyldiaminodiphenylmethane (TGDDM), tetraglycidyldiaminodiphenylsulfone (TGDDS), tetraglycidyl-m-xylylenediamine (TGMXDA), triglycidyl-p-aminophenol, triglycidyl-m-aminophenol, N,N-diglycidylaniline, tetraglycidyl-1,3-bisaminomethylcyclohexane (TG1,3-BAC), triglycidyl isocyanurate (TGIC), and the like; epoxy compounds having a tricyclo[5,2,1,0^{2,6}] decane ring, such as epoxy compounds which can be prepared by a known method that involves polymerizing dicyclopentadiene with a cresol such as metacresol, or the like, or a phenol, then reacting epichlorohydrin; alicyclic epoxy resins; epoxy resins having a sulfur atom in the epoxy resin main chain, such as Flep 10 manufactured by Toray Thiokol Co., Ltd.; urethane-modified epoxy resins having urethane bonds; and rubber-modified epoxy resins containing polybutadiene, liquid polyacrylonitrile-butadiene rubber or acrylonitrile-butadiene rubber (NBR); and the like.

One type thereof may be used independently, or two or more types thereof may be used in combination.

Furthermore, of these, bisphenol A epoxy resins and bisphenol F epoxy resins are preferred from the perspective of curability, heat resistance, durability, and cost.

In the present invention, the epoxy resin (B) preferably uses an epoxy resin with low curing shrinkage. A silicon wafer as a substrate is prone to be damaged, and therefore, using an epoxy resin with high curing shrinkage results in cracking and chipping of the wafer. In recent years, in order to reduce cost, thinner silicon wafers have advanced, and epoxy resins with low curing shrinkage also have an effect of suppressing wafer warping.

From the perspective of reducing curing shrinkage, reduced contact resistance of a formed collector electrode, and more favorable adhesion with a transparent conductive layer, an epoxy resin in which ethylene oxide and/or propylene oxide are added is preferred.

Herein, an epoxy resin to which ethylene oxide and/or propylene oxide are added is obtained by adding (modifying) ethylene and/or propylene when reacting bisphenol A, bisphenol F, and the like with epichlorohydrin to prepare an epoxy resin.

A commercially available product can be used as the epoxy resin to which are added ethylene oxide and/or propylene oxide, and specific examples include ethylene oxide-added bisphenol A epoxy resin (BEO-60E, manufactured by New Japan Chemical Co., Ltd.), propylene oxide-added bisphenol A epoxy resin (BPO-20E, manufactured by New Japan Chemical Co., Ltd.), propylene oxide-added bisphenol A epoxy resin (EP-4010S, manufactured by Adeka Corporation), propylene oxide-added bisphenol A epoxy resin (EP-4000S, manufactured by Adeka Corporation), and the like.

An example of a separate method of adjusting curing shrinkage of the epoxy resin includes using two or more types of epoxy resin with different molecular weights. In particular, a bisphenol A epoxy resin (B1) with an epoxy equivalent weight of 1500 to 4000 g/eq and polyhydric alcohol glycidyl epoxy resin (B2) with an epoxy equivalent weight of 1000 g/eq or less or diluted bisphenol A epoxy resin (B3) are preferably combined, from the perspective of reduced contact resistance of a formed collector electrode, and more favorable adhesion with a transparent conductive layer.

### Bisphenol A Epoxy Resin (B1)

The bisphenol A epoxy resin (B1) is a bisphenol A epoxy resin with an epoxy equivalent weight of 1500 to 4000 g/eq.

The bisphenol A epoxy resin (B1) has an epoxy equivalent weight within the aforementioned range, and therefore, when the bisphenol A epoxy resin (B1) is used as described above, curing shrinkage of the conductive composition of the present invention will be suppressed, and adhesion with regard to a substrate or transparent conductive layer will be favorable. The epoxy equivalent weight is preferably 2000 to 4000 g/eq, and more preferably 2000 to 3500 g/eq from the perspective of lower volume resistivity.

### Polyhydric Alcohol Glycidyl Epoxy Resin (B2)

The polyhydric alcohol glycidyl epoxy resin (B2) is a polyhydric alcohol glycidyl epoxy resin with an epoxy equivalent weight of 1000 g/eq or less.

The polyhydric alcohol glycidyl epoxy resin (B2) has an epoxy equivalent weight within the aforementioned range, and therefore, when the polyhydric alcohol glycidyl epoxy resin (B2) is used as described above, the viscosity of the conductive composition of the present invention will be favorable, and the printing properties will be favorable.

Furthermore, the epoxy equivalent weight of the polyhydric alcohol glycidyl epoxy resin (B2) is preferably 100 to 400 g/eq, and more preferably 100 to 300 g/eq, from the perspective of adequate viscosity when screen printing.

### Diluted Type Bisphenol A Epoxy Resin (B3)

The diluted type bisphenol A epoxy resin (B3) is a bisphenol A epoxy resin with an epoxy equivalent weight of 1000 g/eq or less. The viscosity was reduced using a reactive diluting agent, without impairing the properties of the epoxy resin. The bisphenol A epoxy resin (B3) has an epoxy equivalent weight within the aforementioned range, and therefore, when the bisphenol A epoxy resin (B3) is used as described above, the viscosity of the conductive composition of the present invention will be favorable, and the printing properties will be favorable.

Furthermore, the epoxy equivalent weight of the bisphenol A epoxy resin (B3) is preferably 100 to 400 g/eq, and more preferably 100 to 300 g/eq, from the perspective of adequate viscosity when screen printing.

In the present invention, the amount of the epoxy resin (B) is preferably 2 to 20 parts by mass, more preferably 2 to 15 parts by mass, and even more preferably 2 to 10 parts by mass with regard to 100 parts by mass of the metal powder (A), from the perspective of reduced contact resistance of a formed collector electrode, and more favorable adhesion with a transparent conductive layer.

### Cationic Curing Agent (C)

The cationic curing agent (C) used in the conductive composition of the present invention is not particularly limited, and is preferably an amine-based, sulfonium-based, ammonium-based, or phosphonium-based curing agent.

Specific examples of the cationic curing agent (C) include boron trifluoride ethylamine, boron trifluoride piperidine, boron trifluoride phenol, p-methoxybenzene diazonium hexafluorophosphate, diphenyliodonium hexafluorophosphate, tetraphenyl sulfonium, tetra-n-butyl phosphonium tetraphenylborate, tetra-n-butyl phosphonium-o,o-diethyl phosphorodithioate, sulfonium salt as expressed by the following Formula (I), and the like, and one type thereof may be used independently, or two or more types thereof may be used in combination.

Of these, a sulfonium salt as expressed by the following Formula (I) is preferably used from the perspective of reducing the curing time.

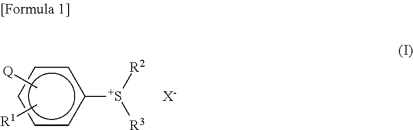

In the formula, R¹ represents a hydrogen atom, alkyl group with 1 to 4 carbon atoms, or a halogen atom: R² represents an alkyl group with 1 to 4 carbon atoms, a benzyl group that may be substituted with an alkyl group with 1 to 4 carbon atoms, or an α-naphthyl methyl group; and R³ represents an alkyl group with 1 to 4 carbon atoms. Furthermore, Q represents a group as expressed by any one of the following Formulas (a) to (c); and X represents SbF₆, PF₆, CF₃SO₃, (CF₃SO₂)₂N, BF₄, B(C₆F₅)₄, or Al(CF₃SO₃)₄.

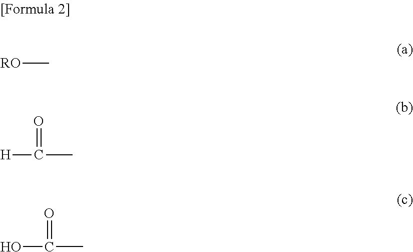

In formula (a), R represents a hydrogen atom, acetyl group, methoxy carbonyl group, or benzyloxy carbonyl group.

Of the sulfonium salts expressed by the aforementioned Formula (I), X in the aforementioned Formula (I) is preferably a sulfonium salt as expressed by SbF₆ from the perspective of being able to form an electrode with favorable solderability, and specific examples include compounds expressed by the following Formulas (1) and (2).

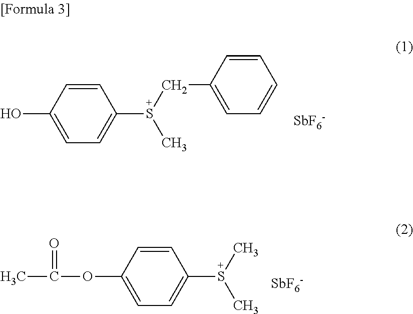

In the present invention, the amount of the cationic curing agent is preferably 1 to 10 parts by mass, and more preferably 1 to 5 parts by mass with regard to 100 parts by mass of the epoxy resin (B), from the perspective that a ring-opening reaction of an epoxy group can be sufficiently advanced by activating with heat.

### Blocked Carboxylic Acid (D)

The blocked carboxylic acid (D) included in the conductive composition of the present invention is a compound obtained by reacting a compound (d1) selected from carboxylic acids and carboxylic acid anhydrides with a vinyl ether compound (d2).

In other words, “blocked” of the blocked carboxylic acid (D) refers to protecting a carboxy group by addition reacting the carboxy group (—COOH) derived from the compound (d1) with a vinyl ether group (—O—CH═CH₂) or vinyl thioether group (—S—CH═CH₂) of the vinyl ether compound (d2).

Note that at least a portion of the carboxyl groups of the blocked carboxylic acid (D) may be blocked, and carboxyl group that are not blocked may partially remain.

Herein, examples of the reaction of the compound (d1) with the vinyl ether compound (d2) include: a form of reacting a carboxylic acid compound with a vinyl ether compound; a form of reacting a carboxylic acid anhydride with a hydroxy vinyl ether compound; a form of addition polymerizing a reaction product of a carboxylic acid anhydride and polyhydric alcohol in a divinyl ether compound; a form of addition polymerizing a dicarboxylic acid and divinyl ether compound; and the like.

### Compound (d1)

Of the compounds (d1) used in generating the blocked carboxylic acid (D), specific examples of the carboxylic acid compound include oxalic acid, malonic acid, succinic acid, adipic acid, glutaric acid, 2-4 diethyl glutaric acid, 2,4-dimethyl glutaric acid, pimelic acid, azelaic acid, sebacic acid, cyclohexane dicarboxylic acid, maleic acid, fumaric acid, diglycolic acid, and the like.

Note that in the present invention, the carboxylic acid compounds include the “reaction product of a carboxylic acid anhydride and polyhydric alcohol” as described in the aforementioned reaction form, and a specific example of the reaction product can be obtained by reacting a carboxylic acid anhydride described below with a polyhydric alcohol (such as ethylene glycol, diethylene glycol, propylene glycol, or the like) from room temperature to 200° C. in a suitable solvent or without a solvent.

Furthermore, of the compounds (d1) used in generating the blocked carboxylic acid (D), specific examples of the carboxylic acid anhydride include succinic acid anhydride, maleic acid anhydride, itaconic acid anhydride, citraconic acid anhydride, tetrahydrophthalic acid anhydride, hexahydrophthalic acid anhydride, 4-methyl tetrahydrophthalic acid anhydride, 4-methyl hexahydrophthatlic acid anhydride, 3-methyl tetrahydrophthalic acid anhydride, dodecenyl succinic acid anhydride, phthalic acid anhydride, diglycolic acid anhydride, glutaric acid anhydride, and the like.

In the present invention, the number of carbon atoms in the compound (d1) is preferably 3 to 9 from the perspective of more favorable adhesion with regard to a transparent conductive layer and formed collector electrode, and the number of carbon atoms of the compound (d1) is more preferably an odd number (in particular, any one of 3, 5, 7, or 9) from the perspective of even more favorable adhesion.

In other words, the compound (d1) is preferably at least one type of dicarboxylic acid selected from the group consisting of malonic acid, glutaric acid, pimelic acid, and azelaic acid.

Although the reason that the adhesion improves is not clear, the reason is thought to be that a portion of the carboxylic acid in which a block of the blocked carboxylic acid (D) is separated reacts with the epoxy resin as described above, and therefore, the distance between the formed collector electrode and transparent conductive layer is reduced, and interaction thereof is increased.

### Vinyl Ether Compound (d2)

The vinyl ether compound (d2) used in generating the blocked carboxylic acid (D) is not particularly limited so long as the compound has a vinyl ether group (—O—CH═CH₂) or a vinyl thioether group (—S—CH═CH₂), and examples include aliphatic vinyl ethers, aliphatic vinyl thioethers, cyclic vinyl ethers, and cyclic vinyl thioethers, and the like.

Specific examples of aliphatic vinyl ethers include: methyl vinyl ethers, ethyl vinyl ethers, isopropyl vinyl ethers, n-propyl vinyl ethers, n-butyl vinyl ethers, isobutyl vinyl ethers, 2-ethyl hexyl vinyl ethers, cyclohexyl vinyl ethers, and other monovinyl ether compounds; butanediol divinyl ethers, cyclohexanediol divinyl ethers, cyclohexane dimethanol dinvyl ethers, diethylene glycol divinyl ethers, triethylene glycol divinyl ethers, tetraethylene glycol dinvinyl ethers, ethylene glycol divinyl ethers, hexanediol divinyl ethers, and other divinyl ether compounds; trimethylol propane trivinyl ethers and other trivinyl ether compounds; pentaerythritol tetravinyl ethers and other tetravinyl ether compounds; and the like. Note that examples of the aliphatic vinyl thioether include thio compounds corresponding to the examples of the aforementioned aliphatic vinyl ethers.

Furthermore, specific examples of the cyclic vinyl ether include 2,3-dihydrofuran, 3,4-dihydrofuran, 2,3-dihydro-2H-pyran, 3,4-dihydro-2H-pyran, 3,4-dihydro-2-methoxy-2H-pyran, 3,4-dihydro-4,4-dimethyl-2H-pyran-2-one, 3,4-dihydro-2-ethoxy-2H-pyran, sodium 3,4-dihydro-2H-pyran-2-carboxylate, and the like. Note that examples of the cyclic vinyl thioether include thio compounds corresponding to the examples of the aforementioned cyclic vinyl ethers.

Furthermore, of the vinyl ether compounds (d2), specific examples of the hydroxy vinyl ether compound used in the reaction with the carboxylic acid anhydride include hydroxymethyl vinyl ethers, hydroxyethyl vinyl ethers, hydroxypropyl vinyl ethers, hydroxybutyl vinyl ethers, hydroxypentyl vinyl ethers, hydroxyhexyl vinyl ethers, hydroxyheptyl vinyl ethers, hydroxyoctyl vinyl ethers, hydroxynonyl vinyl ethers, 4-hydroxycyclohexyl vinyl ethers, 3-hydroxycyclohexyl vinyl ethers, 2-hydroxycyclohexyl vinyl ethers, cyclohexane dimethanol monovinyl ethers, diethylene glycol monovinyl ethers, triethylene glycol monovinyl ethers, tetraethylene glycol monovinyl ethers, and the like.

A synthesizing method of the blocked carboxylic acid (D) using the aforementioned compound (d1) and vinyl ether compound (d2) is not particularly limited, and can be performed in accordance with a conventional addition reaction method. For example, the aforementioned compound (d1) and vinyl ether compound (d2) can be mixed for four hours at 100° C. to synthesize the blocked carboxylic acid (D) in which carboxy group is blocked.

In the present invention, the amount of blocked carboxylic acid (D) is preferably 0.05 to 5 parts by mass with regard to 100 parts by mass of the metal powder (A), and from the perspective of reducing contact resistance of a formed collector electrode, is preferably 0.05 to 1 parts by mass with regard to 100 parts by mass of the metal powder (A).

### Phenoxy Resin (E)

The conductive composition of the present invention preferably contains the phenoxy resin (E) from the perspective being able to obtain a stable paste condition compatible with the epoxy resin (B).

Examples of the phenoxy resin (E) include bisphenol A phenoxy resins and bisphenol F phenoxy resins.

In the present invention, a commercially available product can be used as the phenoxy resin (E), and specific examples thereof include bisphenol A phenoxy resin (1256, manufactured by Japan Epoxy Resin Co., Ltd.), bisphenol A phenoxy resin (YP-50, manufactured by Tohto Kasei Co., Ltd.), bisphenol F phenoxy resin (FX-316, manufactured by Tohto Kasei Co., Ltd.), a copolymer type of bisphenol A and bisphenol F (YP-70, manufactured by Tohto Kasei Co., Ltd.), and the like.

Furthermore, in the present invention, the amount of including the phenoxy resin (E) is preferably 0.1 to 10 parts by mass, and more preferably 0.5 to 5 parts by mass with regard to 100 parts by mass of the metal powder (A), from the perspective of reduced contact resistance of a formed collector electrode, and more favorable adhesion with a transparent conductive layer.

### Fatty Acid Metal Salt (F)

The conductive composition of the present invention preferably contains the fatty acid metal salt (F) from the perspective of reduced contact resistance with a formed collector electrode.

The fatty acid metal salt (F) is not particularly limited so long as a metal salt of an organic carboxylic acid is used, and preferably uses a carboxylic acid metal salt of at least one type of metal selected from the group consisting of silver, magnesium, nickel, copper, zinc, yttrium, zirconium, tin, and lead for example.

Of these, a carboxylic acid metal salt of silver (hereinafter, referred to as “carboxylic acid silver salt”) is preferably used.

Herein, the carboxylic acid silver salt is not particularly limited so long a silver salt of an organic carboxylic acid (fatty acid) is used, and examples include: a fatty acid metal salt (and particularly, a tertiary fatty acid silver salt) described in paragraphs [0063] to [0068] of Japanese Unexamined Patent Application Publication No. 2008-198595A; a fatty acid silver salt described in paragraph [0030] of Japanese Patent No. 4482930B; a fatty acid silver salt having at least one hydroxyl group described in paragraphs [0029] to [0045] of Japanese Unexamined Patent Application Publication No. 2010-92684A; a secondary fatty acid silver salt described in paragraphs [0046] to [0056] of Japanese Unexamined Patent Application Publication No. 2010-92684A; a carboxylic acid silver described in paragraphs [0022] to [0026] of Japanese Unexamined Patent Application Publication No. 2011-35062A; and the like.

In the present invention, the amount of the fatty acid metal salt (F) included is preferably 1 to 10 parts by mass, and more preferably 0.5 to 50 parts by mass with regard to 100 parts by mass of the metal powder (A), from the perspective of further reducing contact resistance of a formed collector electrode.

### Solvent (G)

The conductive composition of the present invention preferably contains the solvent (G) from the perspective of workability such as printing properties or the like.

The solvent (G) is not particular limited so long as the conductive composition of the present invention can be coated on a substrate, and specific examples include butyl carbitol, methyl ethyl ketone, isophorone, α-terpineol, and the like. One type thereof may be used independently, or two or more types may be used in combination.

### Additives

The conductive composition of the present invention may contain a reducing agent or other additive as necessary.

Specific examples of the reducing agent include ethylene glycols and the like. Furthermore, the conductive composition of the present invention is not particularly required for a glass flit generally used as a high-temperature (700 to 800° C.) baked type conductive paste, is preferably less than 0.1 parts by mass with regard to 100 parts by mass of the metal powder (A), and is preferably essentially not included.

A manufacturing method of the conductive composition of the present invention is not particularly limited, and an example includes a method of mixing the aforementioned components using a roll mill, kneader, extruder, universal mixer, or the like.

Solar Cell

A solar cell of the present invention is a solar cell provided with a collector electrode and a transparent conductive layer as a foundation layer of the collector electrode, and is a solar cell where the collector electrode is formed using the conductive composition of the present invention.

An example of a preferred embodiment of the solar cell of the present invention includes a solar cell provided with a transparent conductive layer (for example, TCO) and amorphous silicon layer below and above a n-type single crystal silicon substrate which is at the center, having the transparent conductive layer as a foundation layer, and forming a collector electrode using the conductive composition of the present invention on the transparent conductive layer (for example, a heterojunction solar cell).

The solar cell is a solar cell hybridizing the single crystal silicon and amorphous silicon, which exhibits high conversion efficiency.

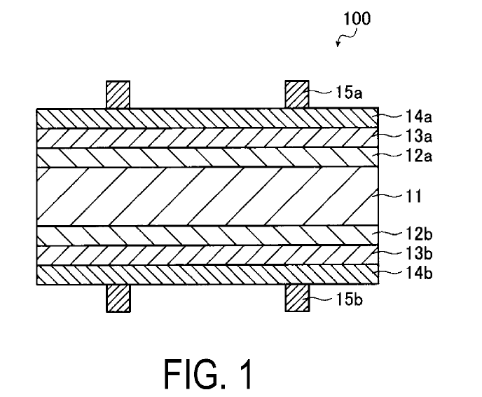

A preferred embodiment of the solar cell of the present invention will be described below using FIG. 1.

As illustrated in FIG. 1, a solar cell 100 is provided with a n-type single crystal silicon substrate 11 at a center, i-type amorphous silicon layers 12a and 12b thereabove and therebelow, a p-type amorphous silicon layer 13a and n-type amorphous silicon layer 13b, transparent conductive layers 14a and 14b, and collector electrodes 15a and 15b formed using the conductive composition of the present invention.

The n-type single crystal silicon substrate is a single crystal silicon layer doped with impurities providing n-type properties. Examples of impurities providing n-type properties include phosphorus, arsenic, and the like.

The i-type amorphous silicon layer is an amorphous silicon layer that is not doped.

The p-type amorphous silicon is an amorphous silicon layer doped with impurities providing p-type properties. Examples of impurities providing p-type properties include boron, aluminum, and the like.

The n-type amorphous silicon is an amorphous silicon layer doped with impurities providing n-type properties. The impurities providing n-type properties are described above. The collector electrode is a collector electrode formed using the conductive composition of the present invention.

The arrangement (pitch), shape, height (preferably several to several ten μM), width, aspect ratio (height/width) (preferably 0.4 or greater), and the like of the collector electrode are not particularly limited.

Note that a plurality of the collector electrodes are normally present as illustrated in FIG. 1. In this case, only a portion of the collector electrodes may be formed by the conductive composition of the present invention, but all of the collector electrodes are preferably formed by the conductive composition of the present invention.

### Transparent Conductive Layer

Specific examples of materials of the transparent conductive layer include: zinc oxide, tin oxide, indium oxide, titanium oxide, and other single metal oxides; indium tin oxide (ITO), indium zinc oxide, indium titanium oxide, tin cadmium oxide, and other various metal oxides; gallium-added zinc oxide, aluminum-added zinc oxide, boron-added zinc oxide, titanium-added zinc oxide, titanium-added indium oxide, zirconium-added indium oxide, fluorine-added tin oxide, and other doped metal oxides; and the like.

### Manufacturing Method of Solar Cell

The method of manufacturing the solar cell of the present invention is not particularly limited, but manufacturing is possible by a method described in Japanese Unexamined Patent Application Publication No. 2010-34162A and the like for example.

Specifically, the i-type amorphous silicon layer 12a is formed by a PECVD (plasma enhanced chemical vapor deposition) method or the like, on a main surface on one side of the n-type single crystal silicon substrate 11. Furthermore, the p-type amorphous silicon layer 13a is formed by the PECVD method or the like on the formed i-type amorphous silicon layer 12a.

Next, the i-type amorphous silicon layer 12b is formed by the PECVD method or the like on one main surface of the n-type single crystal silicon substrate 11. Furthermore, the n-type amorphous silicon layer 13b is formed by the PECVD method or the like on the formed i-type amorphous silicon layer 12b.

Next, transparent conductive layers 14a and 14b of ITO or the like are formed on the p-type amorphous silicon layer 13a and n-type amorphous silicon layer 13b by a sputtering method or the like.

Next, the conductive composition of the present invention is coated on the formed transparent conductive layers 14a and 14b to form wiring, and the formed wiring is heat treated (dried or baked) to form the collector electrode 15a.

A step of forming wiring (wiring forming step) and a step of heat treating wiring (heat treating step) will be described in detail below.

### Wiring Forming Step

The wiring forming step is a step of coating the conductive composition of the present invention on a transparent conductive layer to form wiring.

Herein, specific examples of the coating method include inkjet, screen printing, gravure printing, offset printing, letterpress printing, and the like.

### Heat Treating Step

The heat treating step is a step of heat treating a coating film formed by the wiring forming step to form conductive wiring (collector electrode).

The heat treatment is preferably at a temperature condition of 450° C. or lower, and is specifically a treatment of heating (baking) at 150 to 200° C. for several seconds to several ten minutes.

### EXAMPLES

The conductive composition of the present invention will be described in detail below based on examples.

However, the present invention is not limited to these examples.

### Examples 1 to 9 and Comparative Examples 1 to 3

Silver powder and the like shown in Table 1 below were added to a ball mill at a composition ratio (mass ratio) shown in Table 1 below, and then mixed to prepare a conductive composition.

On the other hand, ITO (indium oxide doped with Sn) was formed as a transparent conductive layer on a surface of soda-lime glass to prepare a glass substrate for evaluation.

Next, the prepared conductive compositions were coated onto the glass substrate by screen printing to form six test patterns having a thin line shape with a 1.5 mm width and 15 mm length at 1.8 mm intervals.

Drying was performed for 30 minutes at 200° C. by an oven to form a conductive film having a thing shape (thin wire electrode), and thus a solar cell sample was prepared.

### Contact Resistance

The resistance value between the thin wire electrodes was measured using a digital multimeter (manufactured by Hioki E.E. Corporation: 3541 RESISTANCE HiTESTER) for the prepared solar cell sample, and the contact resistance was calculated using a Transfer Length Method (TLM Method). The results are shown in Table 1 below.

### Adhesive Properties

After soldering a solder ribbon onto the test pattern (thin wire electrode) of the prepared solar cell sample, a 180° tensile test was performed to determine the peeling strength. The results are shown in Table 1 below. If the peeling strength is 1.0 N or higher, adhesion is deemed to be sufficient.

TABLE 1

| | | Examples | | | | | | |
|---|---|---|---|---|---|---|---|---|
| | | 1 | 2 | 3 | 4 | 5 | 6 | 7 |
| Metal Powder (A) | Spherical Metal Powder A1-1 | 50 | 50 | 50 | 50 | 50 | 50 | 50 |
| | Flaky Metal Powder A2-1 | 50 | 50 | 50 | 50 | 50 | 50 | 50 |
| Epoxy Resin (B) | Bisphenol A Epoxy Resin B1-1 | 2.5 | 2.5 | 2.5 | 2.5 | 2.5 | 2.5 | 2.5 |
| | Bisphenol A Epoxy Resin B1-2 | 1.0 | 1.0 | 1.0 | 1.0 | 1.0 | 1.0 | 1.0 |
| | Polyhydric Alcohol Glycidyl | 1.0 | 1.0 | 1.0 | 1.0 | 1.0 | 1.0 | 1.0 |
| | Epoxy Resin B2-1 | | | | | | | |
| Phenoxy Resin (E) | Bisphenol A Phenoxy Resin | — | — | — | — | — | — | 1.0 |
| Blocked Polycarboxylic | Blocked Polycarboxylic Acid | 0.005 | 1.0 | 1.5 | — | — | — | 1.0 |
| Acid (D) | D-1 (Polymeric) | | | | | | | |
| | Blocked Carboxylic Acid D-2 | — | — | — | 1.0 | — | — | — |
| | (Number of Carbons: 9) | | | | | | | |
| | Blocked Carboxylic Acid D-3 | — | — | — | — | 1.0 | — | — |
| | (Number of Carbons: 3) | | | | | | | |
| | Blocked Carboxylic Acid D-4 | — | — | — | — | — | 1.0 | — |
| | (Number of Carbons: 6) | | | | | | | |
| | Blocked Carboxylic Acid D-5 | — | — | — | — | — | — | — |
| | (Number of Carbons: 10) | | | | | | | |
| Fatty Acid Metal Salt (F) | Sliver polycarboxylate salt | — | — | — | — | — | — | — |
| Cationic Curing Agent (C) | Boron Trifluoride Ethylamine | 0.3 | 0.3 | 0.3 | 0.3 | 0.3 | 0.3 | 0.3 |
| Solvent (G) | Terpineol | 20.0 | 20.0 | 20.0 | 20.0 | 20.0 | 20.0 | 20.0 |

| | | | | | | | |
|---|---|---|---|---|---|---|---|
| Contact Resistance [Ω cm²] | 5.9 | 5.2 | 5.5 | 5.2 | 5.2 | 5.4 | 5.2 |
| Adhesion (Peeling Strength) [N] | 1.2 | 1.4 | 1.5 | 1.2 | 1.4 | 1.1 | 1.5 |
| Failure Mode of Peeling Surface Failed Surface | Cohesive | Cohesive | Cohesive | Cohesive | Cohesive | Cohesive | Cohesive |
| | Failure | Failure | Failure | Failure | Failure | Failure | Failure |
| | Ag/TCO | Ag/TCO | Ag/TCO | Ag/TCO | Ag/TCO | Ag/TCO | Ag/TCO |

| | | Examples | | Comparative Example | | |
|---|---|---|---|---|---|---|
| | | 8 | 9 | 1 | 2 | 3 |
| Metal Powder (A) | Spherical Metal Powder A1-1 | 50 | 50 | 50 | 50 | 50 |
| | Flaky Metal Powder A2-1 | 50 | 50 | 50 | 50 | 50 |
| Epoxy Resin (B) | Bisphenol A Epoxy Resin B1-1 | 2.5 | 2.5 | 2.5 | 2.5 | 2.5 |
| | Bisphenol A Epoxy Resin B1-2 | 1.0 | 1.0 | 2.5 | 2.5 | 2.5 |
| | Polyhydric Alcohol Glycidyl | 1.0 | 1.0 | 1.0 | 1.0 | 1.0 |
| | Epoxy Resin B2-1 | | | | | |
| Phenoxy Resin (E) | Bisphenol A Phenoxy Resin | — | — | — | — | — |
| Blocked Polycarboxylic | Blocked Polycarboxylic Acid | 1.0 | — | — | 1.0 | 10.0 |
| Acid (D) | D-1 (Polymeric) | | | | | |
| | Blocked Carboxylic Acid D-2 | — | — | — | | |
| | (Number of Carbons: 9) | | | | | |
| | Blocked Carboxylic Acid D-3 | — | — | — | — | — |
| | (Number of Carbons: 3) | | | | | |
| | Blocked Carboxylic Acid D-4 | — | — | — | — | — |
| | (Number of Carbons: 6) | | | | | |
| | Blocked Carboxylic Acid D-5 | — | 1.0 | — | — | — |
| | (Number of Carbons: 10) | | | | | |
| Fatty Acid Metal Salt (F) | Sliver polycarboxylate salt | 1.0 | — | — | — | — |
| Cationic Curing Agent (C) | Boron Trifluoride Ethylamine | 0.3 | 0.3 | 0.3 | N/A | N/A |
| Solvent (G) | Terpineol | 20.0 | 20.0 | 20.0 | 20.0 | 20.0 |

| | | | | | |
|---|---|---|---|---|---|
| Contact Resistance [Ω cm²] | 5.2 | 5.8 | 5.3 | — | 11.2 |
| Adhesion (Peeling Strength) [N] | 1.4 | 1.0 | 0.6 | — | 1.0 |
| Failure Mode of Peeling Surface Failed Surface | Cohesive | Cohesive | Interfacial | Did | Cohesive |
| | Failure | Failure | Failure | Not | Failure |
| | Ag/TCO | Ag/TCO | Ag/TCO | Cure | Ag/TCO |

The components shown in Table 1 are as follows.
Spherical Metal Powder A1-1: AgC-103 (Shape: spherical, Average particle size: 1.5 μm, manufactured by Fukuda Metal Foil & Powder Co., Ltd.)
Flaky Metal Powder A2-1: AgC-224 (Shape: flaky, Average thickness: 0.7 μm, manufactured by Fukuda Metal Foil & Powder Co., Ltd.)
Bisphenol A Epoxy Resin B1-1: EP-4100E (manufactured by Adeka Corporation)
Bisphenol A Epoxy Resin B1-2: YD-019 (manufactured by Nippon Steel & Sumitomo Metal Corporation)
Polyhydric Alcohol Glycidyl Eposy Resin B2-1: EX-850 (manufactured by Nagase ChemteX Corporation)
Bisphenol A Phenoxy Resin: YP-50S (manufactured by Nippon Steel & Sumitomo Metal Corporation)
Blocked Carboxylic Acid D-1: SANTASHIDDO G (manufactured by NOF Corporation).
Blocked Carboxylic Acid D-2: Polycarboxylic acid blocking a carboxy group, where 18.8 g of azelaic acid (9 carbon atoms) and 32.8 g of 2-ethylhexyl vinyl ether were reacted for four hours at 100° C. Note that unreacted vinyl ether compounds were removed by distilling.
Blocked Carboxylic Acid D-3: Polycarboxylic acid blocking a carboxy group, where 10.4 g of malonic acid (3 carbon atoms) and 32.8 g of 2-ethylhexyl vinyl ether were reacted for four hours at 100° C. Note that unreacted vinyl ether compounds were removed by distilling.
Blocked Carboxylic Acid D-4: Polycarboxylic acid blocking a carboxy group, where 14.6 g of adipic acid (6 carbon atoms) and 32.8 g of 2-ethylhexyl vinyl ether were reacted for four hours at 100° C. Note that unreacted vinyl ether compounds were removed by distilling.
Blocked Carboxylic Acid D-5: Polycarboxylic acid blocking a carboxy group, where 20.2 g of sebacic acid (10 carbon atoms) and 32.8 g of 2-ethylhexyl vinyl ether were reacted for four hours at 100° C. Note that unreacted vinyl ether compounds were removed by distilling.
Polycarboxylic Acid Silver Salt (1,2,3,4-Butane Tetracarboxylic Acid Silver Salt): First, 50 g of silver oxide (manufactured by Toyo Chemical Industrial Co., Ltd.), 25.29 g of 1,2,3,4-butane tetracarboxylic acid (manufactured by New Japan Chemical Co., Ltd.), and 300 g of methyl ethyl ketone (MEK) were introduced in a ball mill and then reacted by stirring for 24 hours at room temperature. Next, the MEK was removed by suction filtering, and the obtained powder was dried to prepare white 1,2,3,4-butane tetracarboxylic acid silver salt.
Cationic Curing Agent: Boron trifluoride ethylamine (manufactured by Stella Chemifa Corporation)
Solvent: Terpinene: Terpineol (manufactured by Yasuhara Chemical Co., Ltd.)

From the results shown in Table 1, the conductive composition prepared without blending the blocked carboxylic acid (D) was found to have inferior adhesion with a transparent conductive layer (Comparative Example 1).

Furthermore, the conductive composition of Comparative Example 2 prepared without blending the cationic curing agent (C) was found to not cure, and the conductive composition of Comparative Example 3 prepared by increasing the blending amount of the blocked carboxylic acid (D) was found to have increased contact resistance with a formed collector electrode, and to not withstand practical use.

In contrast, the conductive compositions in which the cationic curing agent (C) and blocked carboxylic acid (D) were blended were found to all have low contact resistance with a formed collector electrode, and to have favorable adhesion with a transparent conductive layer (Examples 1 to 9).

In particular, from comparing Examples 4 to 6, adhesion with a transparent conductive layer were more favorable when the number of carbon atoms in the polycarboxylic acid used in generating the blocked carboxylic acid (D) was an odd number.

Furthermore, from comparing Examples 4 to 6 and 9, adhesion with a transparent conductive layer were more favorable when the number of carbon atoms in the polycarboxylic acid used in generating the blocked carboxylic acid (D) was 3 to 9.

### REFERENCE SIGNS LIST

11 n-type single crystal silicon substrate
12a, 12b i-type amorphous silicon layer
13a p-type amorphous silicon layer
13b n-type amorphous silicon layer
14a, 14b Transparent conductive layer
15a, 15b Collector electrode
100 Solar cell

1. A conductive composition for forming a solar cell collector electrode, comprising:
a metal powder (A);
an epoxy resin (B);
a cationic curing agent (C); and
a blocked carboxylic acid (D); wherein
the blocked carboxylic acid (D) is a compound obtained by reacting a compound (d1) selected from carboxylic acids and carboxylic acid anhydrides with a vinyl ether compound (d2).

2. The conductive composition for forming a solar cell collector electrode according to claim 1, wherein the amount of the blocked carboxylic acid (D) is 0.05 to 5 parts by mass with regard to 100 parts by mass of the metal powder (A).

3. The conductive composition for forming a solar cell collector electrode according to claim 1, wherein the metal powder (A) contains both spherical metal powder (A1) and flaky metal powder (A2) at a mass ratio (A1:A2) of 70:30 to 30:70.

4. The conductive composition for forming a solar cell collector electrode according to claim 1, wherein the blocked carboxylic acid (D) is a polymeric blocked carboxylic acid obtained by addition polymerizing a dicarboxylic acid and a divinyl ether compound.

5. The conductive composition for forming a solar cell collector electrode according to claim 1, wherein the number of carbon atoms in the compound (d1) is 3 to 9.

6. The conductive composition for forming a solar cell collector electrode according to claim 1, wherein the number of carbon atoms in the compound (d1) is any one of 3, 5, 7 or 9.

7. The conductive composition for forming a solar cell collector electrode according to claim 1, wherein the compound (d1) is at least one type of dicarboxylic acid selected from the group consisting of malonic acid, glutaric acid, pimelic acid, and azelaic acid.

8. A solar cell, comprising:
a collector electrode; and
a transparent conductive layer as a foundation layer of the collector electrode; wherein
the collector electrode is formed using the conductive composition for forming a solar cell collector electrode according to claim 1.

9. A solar cell module using the solar cell according to claim 8.

10. The conductive composition for forming a solar cell collector electrode according to claim 2, wherein the metal powder (A) contains both spherical metal powder (A1) and flaky metal powder (A2) at a mass ratio (A1:A2) of 70:30 to 30:70.

11. The conductive composition for forming a solar cell collector electrode according to claim 2, wherein the blocked carboxylic acid (D) is a polymeric blocked carboxylic acid obtained by addition polymerizing a dicarboxylic acid and a divinyl ether compound.

12. The conductive composition for forming a solar cell collector electrode according to claim 3, wherein the blocked carboxylic acid (D) is a polymeric blocked carboxylic acid obtained by addition polymerizing a dicarboxylic acid and a divinyl ether compound.

13. The conductive composition for forming a solar cell collector electrode according to claim 2, wherein the number of carbon atoms in the compound (d1) is 3 to 9.

14. The conductive composition for forming a solar cell collector electrode according to claim 3, wherein the number of carbon atoms in the compound (d1) is 3 to 9.

15. The conductive composition for forming a solar cell collector electrode according to claim 2, wherein the number of carbon atoms in the compound (d1) is any one of 3, 5, 7 or 9.

16. The conductive composition for forming a solar cell collector electrode according to claim 3, wherein the number of carbon atoms in the compound (d1) is any one of 3, 5, 7 or 9.

17. The conductive composition for forming a solar cell collector electrode according to claim 2, wherein the compound (d1) is at least one type of dicarboxylic acid selected from the group consisting of malonic acid, glutaric acid, pimelic acid, and azelaic acid.

18. The conductive composition for forming a solar cell collector electrode according to claim 3, wherein the compound (d1) is at least one type of dicarboxylic acid selected from the group consisting of malonic acid, glutaric acid, pimelic acid, and azelaic acid.

19. A solar cell, comprising:
a collector electrode; and
a transparent conductive layer as a foundation layer of the collector electrode; wherein
the collector electrode is formed using the conductive composition for forming a solar cell collector electrode according to claim 2.

20. A solar cell, comprising:
a collector electrode; and
a transparent conductive layer as a foundation layer of the collector electrode; wherein
the collector electrode is formed using the conductive composition for forming a solar cell collector electrode according to claim 3.
